(19) United States
(12) Patent Application Publication
(10) Pub. No.: US 2025/0048889 A1
(43) Pub. Date: Feb. 6, 2025

(54) COVER WINDOW, DISPLAY DEVICE INCLUDING THE SAME, AND METHOD OF MANUFACTURING THE COVER WINDOW

(71) Applicant: Samsung Display Co., LTD., Yongin-si (KR)

(72) Inventor: Soojin SUNG, Yongin-si (KR)

(21) Appl. No.: 18/658,440

(22) Filed: May 8, 2024

(30) Foreign Application Priority Data
Aug. 2, 2023 (KR) 10-2023-0100907

(51) Int. Cl. H10K 59/80; H10K 59/12

(52) U.S. Cl. CPC H10K 59/873; H10K 59/1201; H10K 59/8792

(57) ABSTRACT

A cover window includes: a resin part including a light transmitting area and a non-light transmitting area surrounding at least a portion of the light transmitting area; and a particle layer inside the resin part, overlapping the non-light transmitting area, and including a plurality of particles.

### CROSS-REFERENCE TO RELATED APPLICATION

The present application claims priority to and the benefit of Korean Patent Application No. 10-2023-0100907, filed on Aug. 2, 2023, in the Korean Intellectual Property Office (KIPO), the entire disclosure which is incorporated herein by reference.

### BACKGROUND

### 1. Field

Aspects of some embodiments relate to a cover window, a display device including the cover window, and a method of manufacturing the cover window.

### 2. Description of the Related Art

The display device is a device that displays an image for providing visual information to a user. Among display devices, an organic light emitting diode display has recently attracted attention.

The display device may include a display panel. In addition, the display device may include a cover window attached on the display panel. The cover window may protect the display panel. The cover window may include a light transmitting area and a non-light transmitting area surrounding the light transmitting area. A black matrix may be located in the non-light transmitting area.

The above information disclosed in this Background section is only for enhancement of understanding of the background and therefore the information discussed in this Background section does not necessarily constitute prior art.

### SUMMARY

Aspects of some embodiments include a cover window with relatively improved reliability.

Aspects of some embodiments include a display device including the cover window.

Aspects of some embodiments include a method of manufacturing the cover window.

A cover window according to some embodiments includes a resin part including a light transmitting area and a non-light transmitting area surrounding at least a portion of the light transmitting area and a particle layer inside the resin part, overlapping the non-light transmitting area, and including a plurality of particles.

According to some embodiments, the resin part may include a first surface and a second surface facing the first surface.

According to some embodiments, the particle layer may be adjacent to the first surface.

According to some embodiments, the particle layer may be spaced apart from the second surface.

According to some embodiments, each of the plurality of particles may include magnetic particle.

According to some embodiments, each of the plurality of particles may include at least one of iron, nickel, cobalt, or iron oxide.

According to some embodiments, a density of each of the plurality of particles and a density of the resin part may be different from each other.

According to some embodiments, the density of each of the plurality of particles may be greater than the density of the resin part.

According to some embodiments, each color of the plurality of particles may be black.

According to some embodiments, each of the plurality of particles includes magnetic particle and a coating layer surrounding at least a portion of the magnetic particle.

According to some embodiments, the coating layer may have a black color.

According to some embodiments, a portion of the resin part overlapping the non-light transmitting area may include the first portion where the particle layer is located and the second portion adjacent to the first portion in a thickness direction.

A display device according to some embodiments includes a display panel and a cover window on the display panel and including a light transmitting area and a non-light transmitting area surrounding at least a portion of the light transmitting area, the cover window including a resin part and a particle layer, wherein the particle layer is in the resin part, overlaps the non-light transmitting layer, and includes a plurality of particles.

According to some embodiments, the resin part may include a first surface and a second surface facing the first surface.

According to some embodiments, the particle layer may be adjacent to the first surface.

According to some embodiments, the particle layer may be spaced apart from the second surface.

According to some embodiments, each of the plurality of particles may include magnetic particle.

According to some embodiments, each of the plurality of particles may include at least one of iron, nickel, cobalt, or iron oxide.

A method of manufacturing a cover window according to some embodiments includes forming a first resin part overlapping a light transmitting area on a stage, forming a second resin part overlapping a non-light transmitting area surrounding at least a portion of the light transmitting area on the stage, placing a magnet to move the plurality of particles toward the magnet and curing the first resin part and the second resin part.

According to some embodiments, the second resin part may include a plurality of particles.

According to some embodiments, the first resin part and the second resin part may include the same material.

According to some embodiments, each of the plurality of particles may include at least one of iron, nickel, cobalt, or iron oxide.

According to some embodiments, the moving the plurality of particles toward the magnet may include moving the plurality of particles toward the stage by placing the magnet under the stage.

According to some embodiments, the forming the second resin part may proceed after the forming the first resin part.

According to some embodiments, the cover window according to some embodiments may include a light transmitting area and a non-light transmitting area. According to some embodiments, the light transmitting area may overlap a display area of the display panel. According to some embodiments, the non-light transmitting area may overlap a non-display area of the display panel. According to some embodiments, the cover window may include a resin part and a particle layer including a plurality of particles. According to some embodiments, the particle layer may overlap the non-light transmitting area.

Accordingly, the particle layer may cover a driver located in the non-display area. That is, the particle layer may prevent or reduce visibility of the driver by a user of the display device.

In addition, the particle layer may be located inside the resin part. Accordingly, an interface may not be formed between the particle layer and the resin part. Accordingly, moisture, contaminants, and the like may not penetrate into the interface between the particle layer and the resin part. Accordingly, the cover window, the particle layer, and the like may not be discolored. In addition, the interface between the particle layer and the resin part may not be separated.

A method of manufacturing a cover window according to some embodiments includes forming a first resin part overlapping a light transmitting area on a stage, forming a second resin part overlapping a non-light transmitting area surrounding at least a portion of the light transmitting area on the stage, placing a magnet to move the plurality of particles toward the magnet and curing the first resin part and the second resin part.

That is, the particle layer may be formed when the plurality of particles are moved toward the magnet. After the particle layer is formed, the first resin part and the second resin part may be simultaneously cured. Therefore, the cover window including the particle layer may be manufactured by a single curing process, thereby relatively simplifying a manufacturing process of the cover window.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a cover window according to some embodiments.

FIG. 2 is a cross-sectional view of an example of the cover window of FIG. 1 taken along the line I-I′.

FIG. 3 is a cross-sectional view illustrating another example of the cover window of FIG. 1 taken along the line I-I′.

FIG. 4 is a plan view illustrating a display panel.

FIG. 5 is a cross-sectional view illustrating a pixel included in the display panel of FIG. 4.

FIG. 6 is a cross-sectional view illustrating a display device according to some embodiments.

FIGS. 7 to 11 are cross-sectional views illustrating a method of manufacturing the display device and the cover window of FIG. 6 according to some embodiments.

FIGS. 12 to 16 are cross-sectional views illustrating method of manufacturing a cover window according to some embodiments.

### DETAILED DESCRIPTION

Hereinafter, aspects of a display device according to some embodiments will be described in more detail with reference to the accompanying drawings. The same reference numerals are used for the same components in the drawings, and some redundant descriptions of the same components may be omitted.

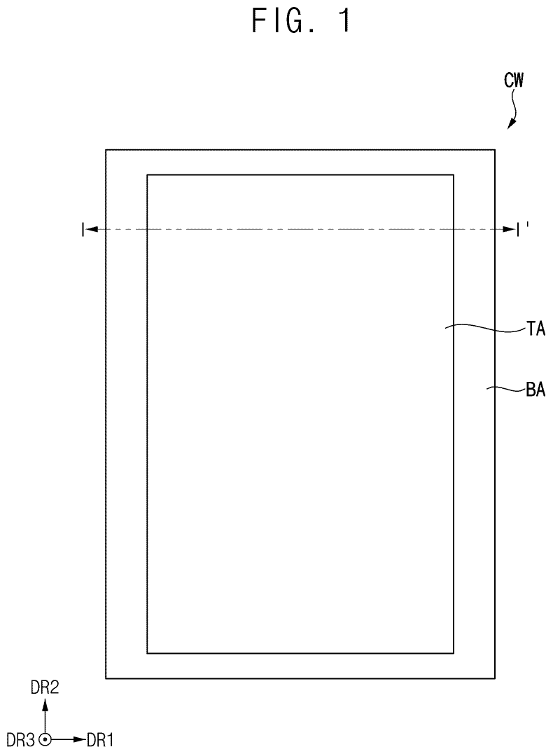

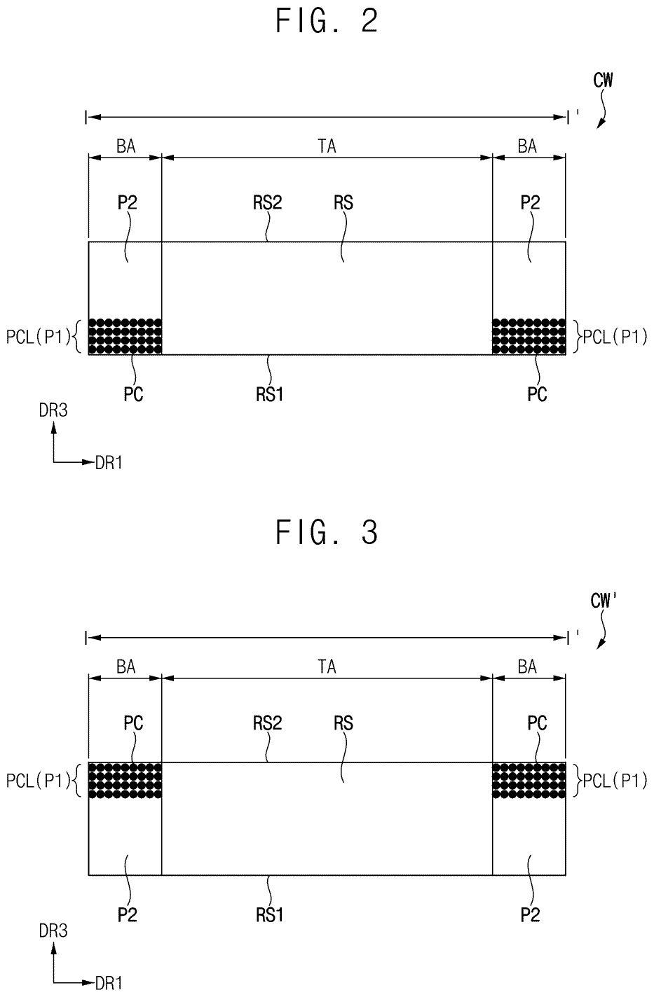

FIG. 1 is a plan view illustrating a cover window according to some embodiments. FIG. 2 is a cross-sectional view of an example of the cover window of FIG. 1 taken along the line I-I′.

Referring to FIG. 1, a cover window CW according to some embodiments may include a light transmitting area TA and a non-light transmitting area BA. The non-light transmitting area BA may surround at least a portion of the light transmitting area TA.

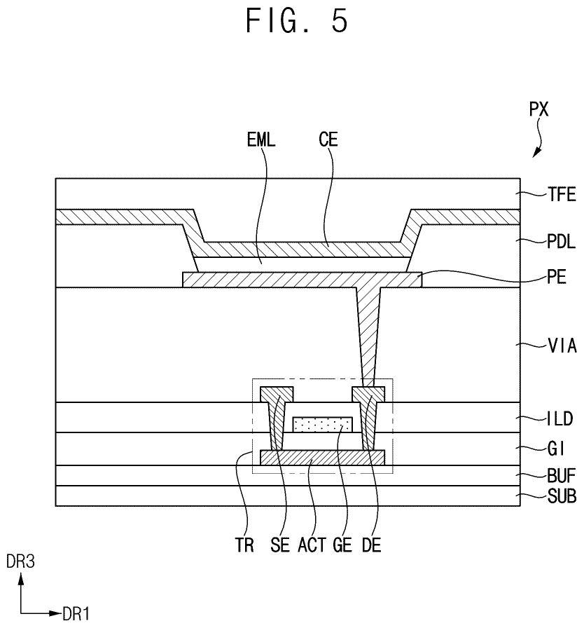

For example, the light-transmitting area TA may overlap a display area (e.g., a display area DA of FIG. 5) of the display panel (e.g., a display panel PNL of FIG. 5). That is, the light transmitting area TA may be an area through which light provided from the display panel is transmitted.

In addition, the non-light transmitting area BA may overlap a non-display area (e.g., a non-display area NDA of FIG. 5) of the display panel. That is, the non-light transmitting area BA may be an area through which light is not transmitted.

A first direction DR1 and a second direction DR2 crossing the first direction DR1 may be defined. In addition, a third direction DR3 perpendicular or normal to a plane formed by the first direction DR1 and the second direction DR2 may be defined.

Referring to FIGS. 1 and 2, the cover window CW may include a resin part RS and a particle layer PCL.

As described above, the cover window CW may include the light transmitting area TA and the non-light transmitting area BA. As the cover window CW includes the light transmitting area TA and the non-light transmitting area BA, the resin part RS may also include the light transmitting area TA and the non-light transmitting area BA.

The resin part RS may overlap the light transmitting area TA and the non-light transmitting area BA. That is, the resin part RS may be arranged over the light transmitting area TA and the non-light transmitting area BA entirely.

The resin part RS may include a first surface RS1 and a second surface RS2. The second surface RS2 may face the first surface RS1. That is, the second surface RS2 may be spaced apart from the first surface RS1 in the third direction DR3.

For example, the resin part RS may include an epoxy resin, an acrylic resin, a polyurethane resin, a polyethylene resin, or the like. These may be used alone or in combination with each other. However, embodiments according to the present disclosure are not limited thereto, and the resin part RS may include other types of resin materials.

According to some embodiments, the particle layer PCL may be located inside the resin part RS. The particle layer PCL may overlap the non-light transmitting area BA. The particle layer PCL may include a plurality of particles PC. That is, the particle layer PCL may mean a portion in the resin part RS in which the plurality of particles PC are located. The number of the plurality of particles PC forming the particle layer PCL may be variously set.

A portion of the resin part RS overlapping the non-light transmitting area BA, may include a first portion P1 and a second portion P2. The first portion P1 may be a portion where the particle layer PCL is located. The second portion P2 may be a portion where the particle layer PCL is not located. That is, in a portion overlapping the non-light transmitting area BA of the resin part RS, the first portion P1 may refer to the rest of the portion where the second portion P2 is not located. The second portion P2 may be adjacent to the first portion P1 in a thickness direction of the resin part RS. For example, the second portion P2 may be adjacent to the first portion P1 in the third direction DR3.

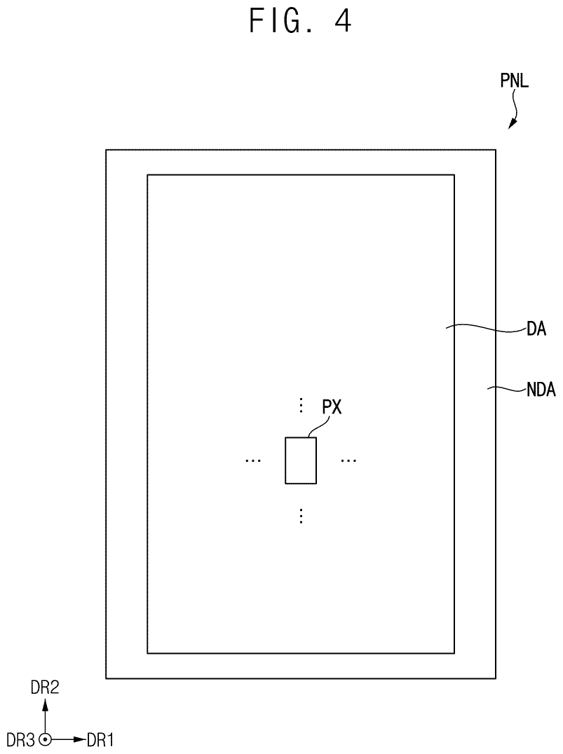

According to some embodiments, the particle layer PCL may be located adjacent to the first surface RS1. In addition, the particle layer PCL may be arranged to be spaced apart from the second surface RS2. For example, the particle layer PCL may be spaced apart from the second surface RS2 in a direction opposite to the third direction DR3. For example, a display panel (e.g., a display panel PNL of FIG. 4) may be adjacent to the first surface RS1.

According to some embodiments, each of the plurality of particles PC may include magnetic particle. For example, each of the plurality of particles PC may include iron, nickel, cobalt, iron oxide, or the like. These may be used alone or in combination with each other.

According to some embodiments, each color of the plurality of particles PC may be black. That is, each of the plurality of particles PC may include a material having a black color. For example, each of the plurality of particles PC may include a pigment or dye having a black color.

According to some embodiments, each of the plurality of particles PC may include a magnetic particle and a coating layer surrounding at least a portion of the magnetic particle. The coating layer may include a black-based material. For example, the coating layer may include a black-based pigment or dye.

According to some embodiments, each of the plurality of particles PC may include only magnetic particle. In this case, a color of the magnetic particle may be black.

According to some embodiments, each color of the plurality of particles PC may include a color of a different series from black. For example, each of the plurality of particles PC may include a pigment or dye having a different color from black.

As will be described later with reference to FIG. 10, the particle layer PCL may be located adjacent to the first surface RS1 as each of the plurality of particles PC includes magnetic particle.

A density of each of the plurality of particles PC may be different from a density of the resin part RS. According to some embodiments, the density of each of a plurality of particles PC may be greater than the density of the resin part RS. Accordingly, the particle layer PCL including a plurality of particles PC may be located adjacent to the first surface RS1.

That is, due to a difference in density between each of the plurality of particles PC and the resin part RS, the particle layer PCL may move to a surface of the resin part RS. In this case, each of the plurality of particles PC may not include a magnetic material.

FIG. 3 is a cross-sectional view illustrating another example of the cover window of FIG. 1 taken along the line I-I′.

A cover window CW described with reference to FIG. 3 may be substantially the same as or similar to the cover window CW described with reference to FIG. 2 except for configurations of the particle layer PCL, the first portion P1, and the second portion P2. Therefore, some duplicated explanations of the same or similar components may be omitted or simplified.

Referring to FIG. 3, according to some embodiments, the particle layer PCL may be adjacent to the second surface RS2. In addition, the particle layer PCL may be spaced apart from the first surface RS1. In this case, the first portion P1 where the particle layer PCL is located may be adjacent to the second portion P2 where the particle layer is not located in the third direction DR3.

FIG. 4 is a plan view illustrating a display panel.

Referring to FIG. 4, the display panel PNL may include the display area DA and the non-display area NDA. The display area DA may be defined as an area for generating light and displaying images. The non-display area NDA may be an area that does not display images. In addition, the non-display area NDA may surround at least a portion of the display area DA.

The display area DA may overlap a light transmitting area (e.g., the light transmitting area TA of FIG. 1) of the cover window (e.g., the cover window CW of FIG. 1). In addition, the non-display area NDA may overlap a non-light transmitting area (e.g., the non-light transmitting area BA of FIG. 1) of the cover window.

A plurality of pixels may be located in the display area DA. For example, a pixel PX may be located in the display area DA. Each of the plurality of pixels may emit light. For example, the pixel PX may emit light. The plurality of pixels may be repeatedly arranged in the first direction DR1 and the second direction DR2.

The non-display area NDA may include a driver. For example, the driver may include a driving controller, a gate driver, a data driver, and the like.

FIG. 5 is a cross-sectional view illustrating a pixel included in the display panel of FIG. 4.

Referring to FIG. 5, the pixel PX may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

The transistor TR may include the active layer ACT, the source electrode SE, the gate electrode GE, and the drain electrode DE.

The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and the like.

Alternatively, the substrate SUB may include a quartz substrate, a synthetic quartz substrate, a calcium fluoride substrate, a fluorine-doped quartz substrate, a sodalime substrate, a non-alkali glass substrate, or the like. These materials may be used alone or in combination with each other.

The buffer layer BUF may be located on the substrate SUB. The buffer layer BUF may prevent metal atoms or impurities from diffusing from the substrate SUB to the transistor TR. In addition, the buffer layer BUF can improve the flatness of a surface of the substrate SUB when the surface of the substrate SUB is not uniform.

For example, the buffer layer BUF may include an inorganic material such as silicon oxide, silicon nitride, silicon oxynitride, or the like. These materials may be used alone or in combination with each other.

The active layer ACT may be located on the buffer layer BUF. The active layer ACT may include an inorganic semiconductor (e.g., amorphous silicon, polysilicon, a metal oxide semiconductor,), an organic semiconductor, and the like. These materials may be used alone or in combination with each other. The active layer ACT may include a source area, a drain area, and a channel area located between the source area and the drain area.

The metal oxide semiconductor may include a binary compound (“ABₓ”), a ternary compound (“ABₓC_{y}”), a tetragonal compound (“ABₓC_{y}D_{z}”), and the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be located on the buffer layer BUF. The gate insulating layer GI may sufficiently cover the active layer ACT, and may have a substantially flat upper surface without generating a step around the active layer ACT. Alternatively, the gate insulating layer GI may cover the active layer ACT and may be arranged along a profile of the active layer ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and the like. These materials may be used alone or in combination with each other.

The gate electrode GE may be located on the gate insulating layer GI. The gate electrode GE may overlap the channel area of the active layer ACT.

The gate electrode GE may include a metal, an alloy metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. In addition, examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be located on the gate insulating layer GI. The interlayer insulating layer ILD may sufficiently cover the gate electrode GE, and may have a substantially flat upper surface without generating a step around the gate electrode GE. Alternatively, the interlayer insulating layer ILD may cover the gate electrode GE, and may be arranged along a profile of the gate electrode GE.

For example, the interlayer insulating layer ILD may include inorganic materials such as silicon oxide, silicon nitride, silicon carbide, silicon oxynitride, silicon oxycarbide, or the like. These materials may be used alone or in combination with each other.

The source electrode SE may be located on the interlayer insulating layer ILD. The source electrode SE may be connected to the source area of the active layer ACT through a contact hole penetrating the gate insulating layer GI and the interlayer insulating layer ILD.

The drain electrode DE may be located on the interlayer insulating layer ILD. The drain electrode DE may be connected to the drain area of the active layer ACT through a contact hole penetrating the gate insulating layer GI and the interlayer insulating layer ILD.

For example, the source electrode SE may include a metal, an alloy, a metal nitride, a conductive metal oxide, a transparent conductive material, and the like. These materials may be used alone or in combination with each other. The drain electrode DE may be formed through the same process as the source electrode SE and may include the same material as the source electrode SE.

The via insulating layer VIA may be located on the interlayer insulating layer ILD. The via insulating layer VIA may sufficiently cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be located on the via insulating layer VIA. The pixel electrode PE may be connected to the drain electrode DE through a contact hole penetrating the via insulating layer VIA.

The pixel electrode PE may include a metal, an alloy, a metal nitride, a conductive metal oxide, a transparent conductive material, or the like. These materials be used alone or in combination with each other. According to some embodiments, the pixel electrode PE may have a stacked structure including ITO/Ag/ITO. For example, the pixel electrode PE may operate as an anode.

The pixel defining layer PDL may be located on the via insulating layer VIA. The pixel defining layer PDL may cover side portions of the pixel electrode PE. In addition, an opening exposing a portion of the upper surface of the pixel electrode PE may be defined in the pixel defining layer PDL.

For example, the pixel defining layer PDL may include an inorganic material or an organic material. According to some embodiments, the pixel defining layer PDL may include an organic material such as an epoxy resin, a siloxane resin, or the like. These materials may be used alone or in combination with each other. According to some embodiments, the pixel defining layer PDL may further include a light blocking material containing a black pigment, a black dye, and the like.

The light emitting layer EML may be located on the pixel electrode PE. The light emitting layer EML may include an organic material that emits light of a color (e.g., a set or predetermined color). For example, the light emitting layer EML may include an organic material that emits red light. However, embodiments according to the present disclosure are not limited thereto, and the light emitting layer EML may emit light of a different color from red light.

The common electrode CE may be located on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

The encapsulation layer TFE may be located on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

For example, the inorganic layer may include silicon oxide, silicon nitride, silicon oxynitride, and the like. These materials may be used alone or in combination with each other. The organic layer may include a polymer cured product such as polyacrylate.

Although aspects of the pixel PX according to some embodiments have been described with reference to FIG. 5, the pixel PX is not limited to the structure shown in FIG. 5. That is, the pixel PX may include all structures that receive an electrical signal and emit light having a luminance corresponding to the intensity of the electrical signal.

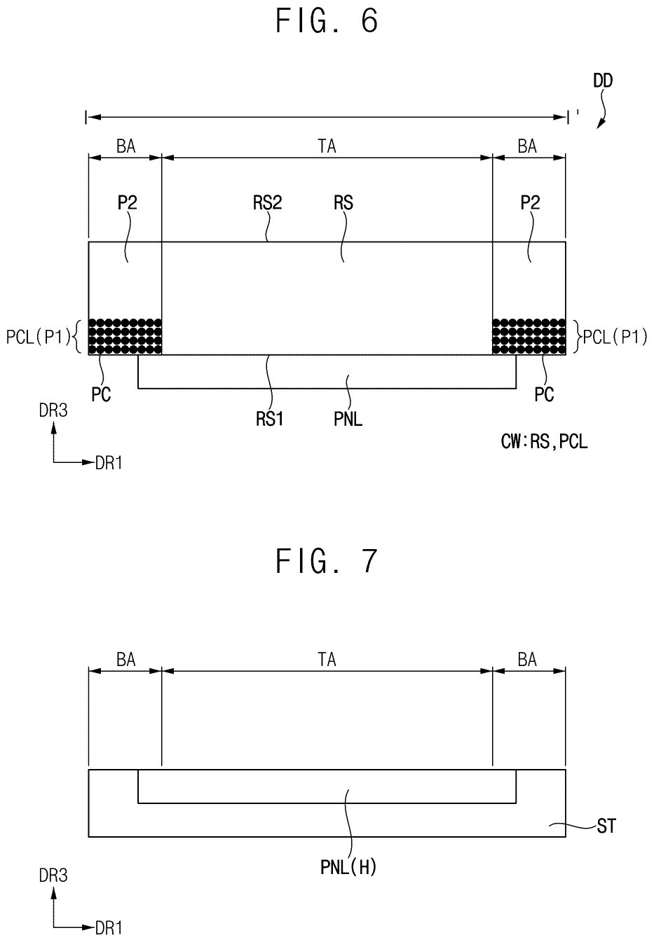

FIG. 6 is a cross-sectional view illustrating a display device according to some embodiments.

Referring to FIGS. 4 and 6, a display device DD according to some embodiments may include the display panel PNL and the cover window CW. The cover window CW may be located on the display panel PNL. That is, the display device DD may include the display panel PNL of FIG. 4 and the cover window CW of FIG. 2 located on the display panel PNL.

As described above, the particle layer PCL may overlap the non-light transmitting area BA. In addition, the non-light transmitting area BA may overlap the non-display area NDA. Accordingly, the particle layer PCL may cover the driver such as a driving controller, a gate driver, and a data driver located in the non-display area NDA. That is, the particle layer PCL may prevent or reduce instances of the driver being visually recognized by a user of the display device DD. In addition, the particle layer PCL may prevent or reduce instances of a gate line, a data line, and the like, from being visually recognized by the user of the display device DD. That is, the particle layer PCL may serve as a black matrix.

In addition, the particle layer may be located inside the resin part. Accordingly, an interface may not be formed between the particle layer and the resin part. Accordingly, moisture and the like may not penetrate into the interface between the particle layer and the resin part. Accordingly, the cover window, the particle layer, and the like may not be discolored. In addition, the interface between the particle layer and the resin part may not be separated.

FIGS. 7 to 11 are cross-sectional views illustrating a method of manufacturing the display device and the cover window of FIG. 6 according to some embodiments.

Referring to FIG. 7, a stage ST may be provided. A groove H may be defined in the stage ST. The groove H may be a portion obtained by removing a portion of the stage ST from an upper surface of the stage ST.

The display panel PNL may be provided on the stage ST. For example, the display panel PNL may be seated in the groove H. The display panel PNL may overlap the light transmitting area TA. In addition, the display panel PNL may partially overlap the non-light transmitting area BA. The non-light transmitting area BA may surround at least a portion of the light transmitting area TA.

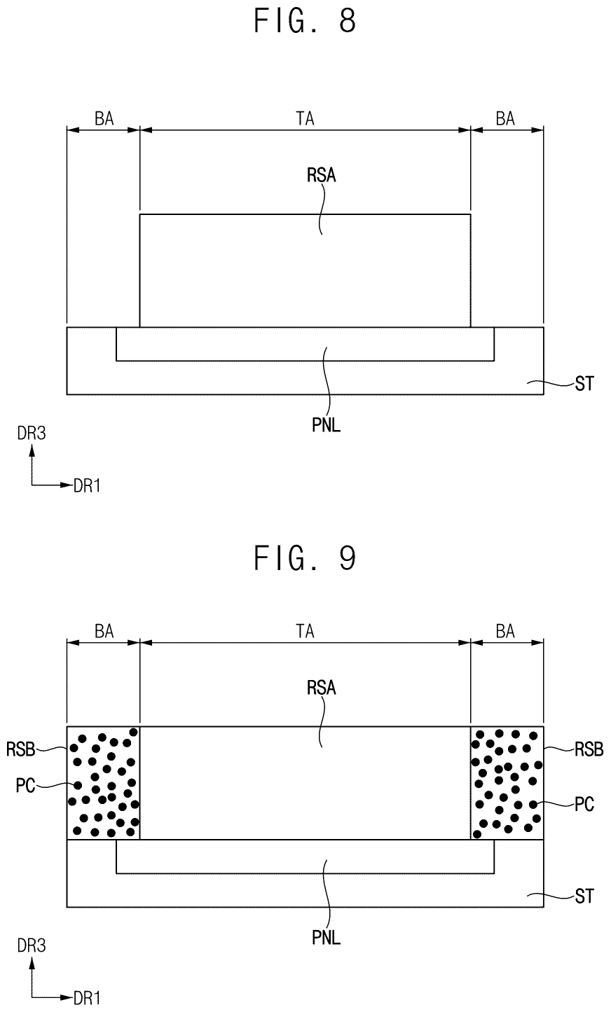

Referring to FIG. 8, a first resin part RSA may be formed on the stage ST. The first resin part RSA may overlap the light transmitting area TA. For example, the first resin part RSA may include an epoxy resin, an acrylic resin, a polyurethane resin, a polyethylene resin, or the like. These may be used alone or in combination with each other.

Referring to FIG. 9, a second resin part RSB including a plurality of particles PC may be formed on the stage ST. The second resin part RSB may overlap the non-light transmitting area BA. For example, the second resin part RSB may include an epoxy resin, an acrylic resin, a polyurethane resin, a polyethylene resin, or the like. These may be used alone or in combination with each other.

According to some embodiments, the second resin part RSB and the first resin part RSA may include the same material. According to some embodiments, the second resin part RSB and the first resin part RSA may include different materials.

According to some embodiments, each of the plurality of particles PC may include magnetic particle. For example, each of the plurality of particles PC may include iron, nickel, cobalt, iron oxide, or the like. These may be used alone or in combination with each other.

Referring to FIGS. 8 and 9, according to some embodiments, after the first resin part RSA is formed on the stage ST, the second resin part RSB may be formed on the stage ST. According to some embodiments, after the second resin part RSB is formed on the stage ST, the first resin part RSA may be formed on the stage ST.

Referring to FIG. 10, according to some embodiments, a magnet MG may be located below the stage ST. The magnet MG may overlap the non-light transmitting area BA. Accordingly, the plurality of particles PC including the magnetic particle may move toward the magnet MG. That is, the plurality of particles PC may move toward the stage ST.

Accordingly, the plurality of particles PC may form the particle layer PCL. That is, the second resin part RSB may include a first portion P1 and a second portion P2. The first portion P1 may be a portion where the particle layer PCL is located. The second portion P2 may be a portion where the particle layer PCL is not located. The second portion P2 may be adjacent to the first portion P1 in the third direction DR3.

According to some embodiments, the magnet MG may be located on the second resin part RSB. That is, the magnet MG may be spaced apart from the second resin part RSB in the third direction DR3. In this case, the plurality of particles PC may move in a direction away from the stage ST. That is, the plurality of particles PC may move in the third direction DR3.

After the particle layer PCL is formed, the first resin part RSA and the second resin part RSB may be cured. For example, the first resin part RSA and the second resin part RSB may be thermally cured or UV cured. According to some embodiments, the first resin part RSA and the second resin part RSB may be simultaneously cured. That is, a manufacturing process of the cover window may be simplified by manufacturing the cover window CW including the particle layer PCL through a single curing process.

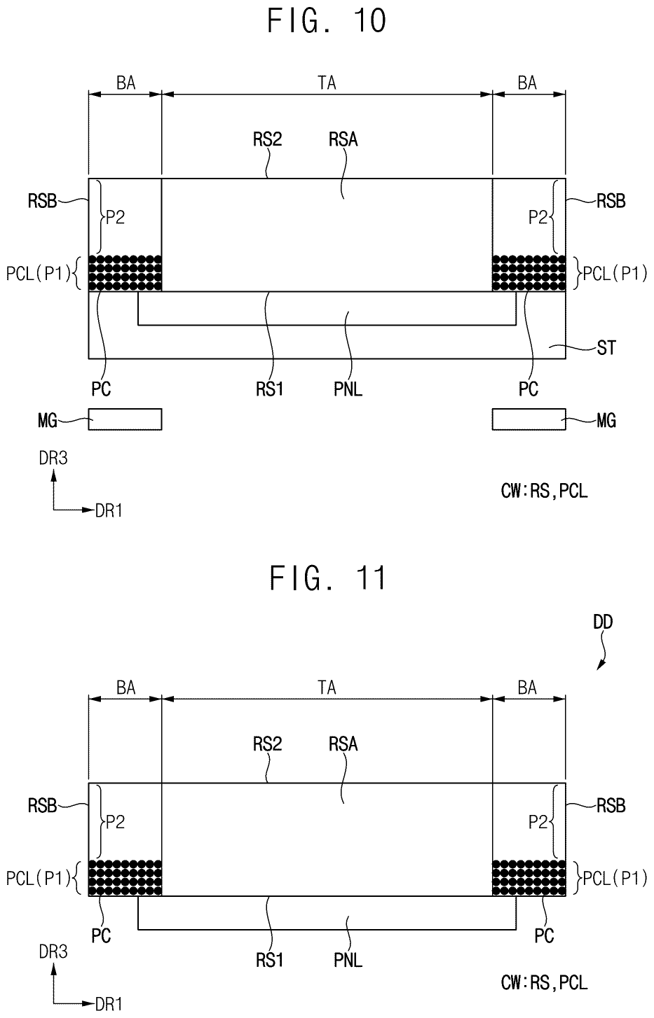

Referring to FIG. 11, the stage ST may be removed.

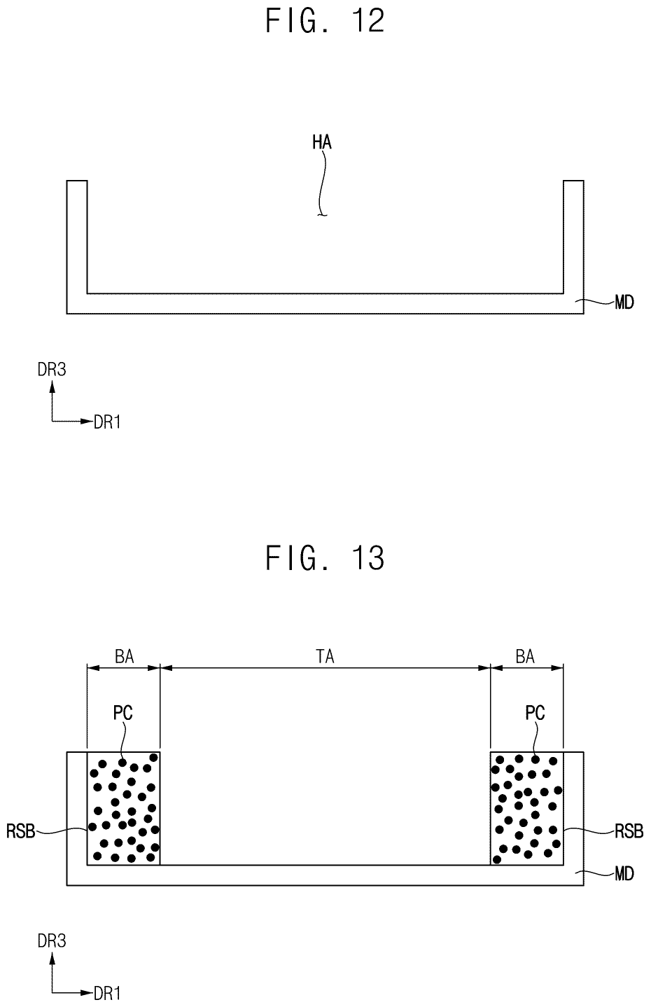

FIGS. 12 to 16 are cross-sectional views illustrating a manufacturing method of a cover window according to some embodiments.

Referring to FIG. 12, a mold MD may be provided. The mold MD may include a seating part HA. The seating part HA may have a rectangular shape in a plan view.

Referring to FIG. 13, the second resin part RSB including the plurality of particles PC may be formed on the mold MD. For example, the second resin part RSB may be formed inside the seating part HA. The second resin part RSB may overlap the non-light transmitting area BA.

For example, the second resin part RSB may include an epoxy resin, an acrylic resin, a polyurethane resin, a polyethylene resin, or the like. These may be used alone or in combination with each other.

For example, each of the plurality of particles PC may include a magnetic particle. For example, each of the plurality of particles PC may include iron, nickel, cobalt, iron oxide, or the like. These may be used alone or in combination with each other.

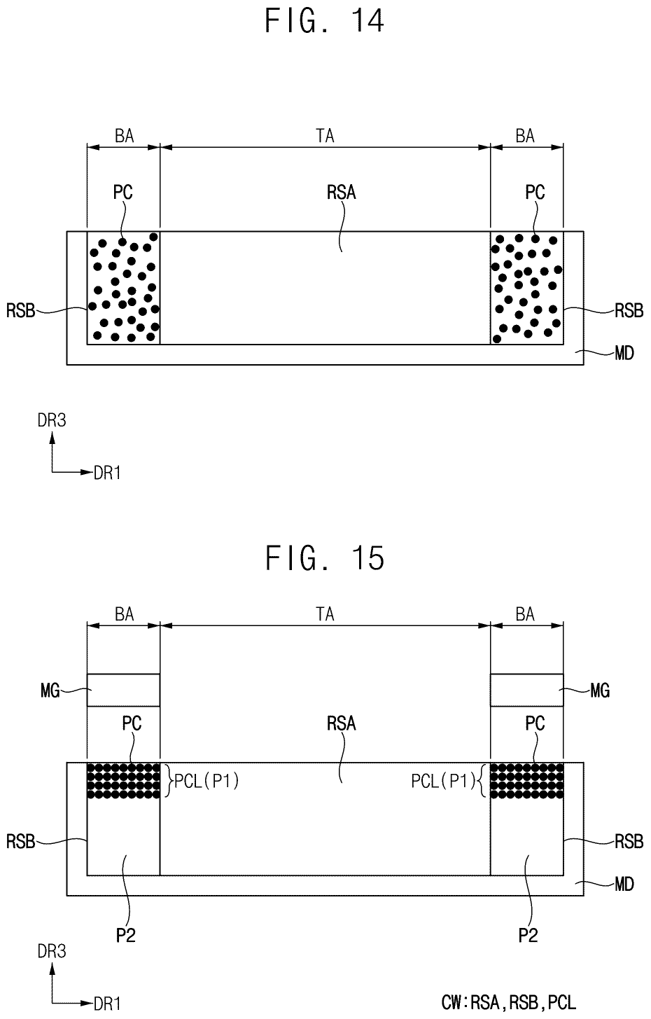

Referring to FIG. 14, the first resin part RSA may be formed on the mold MD. For example, the first resin part RSA may be formed inside the seating part HA. The first resin part RSA may overlap the light transmitting area TA.

For example, the first resin part RSA may include an epoxy resin, an acrylic resin, a polyurethane resin, a polyethylene resin, or the like. These may be used alone or in combination with each other.

According to some embodiments, the second resin part RSB and the first resin part RSA may include the same material. According to some embodiments, the second resin part RSB and the first resin part RSA may include different materials.

Referring to FIGS. 13 and 14, according to some embodiments, after the second resin part RSB is formed on the mold MD, the first resin part RSA may be formed on the mold MD. According to some embodiments, after the first resin part RSA is formed on the mold MD, the second resin part RSB may be formed on the mold MD.

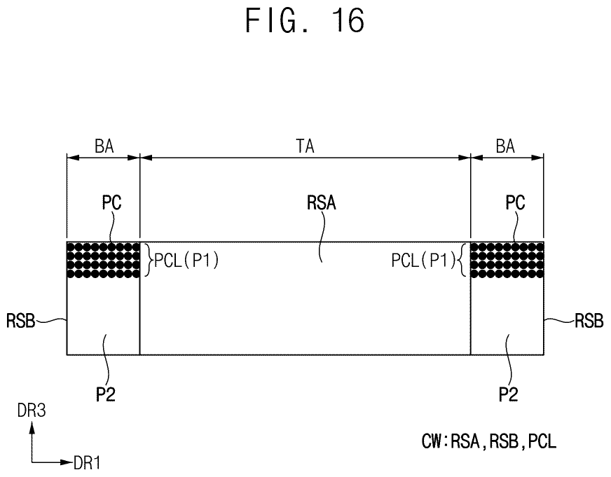

Referring to FIG. 15, according to some embodiments, the magnet MG may be located on the second resin part RSB. The magnet MG may overlap the non-light transmitting area BA.

Accordingly, the plurality of particles PC may move toward the magnet MG. For example, the plurality of particles PC may move in the third direction DR3.

Accordingly, the plurality of particles PC may form the particle layer PCL. That is, the second resin part RSB may include a first portion P1 and a second portion P2. The first portion P1 may be a portion where the particle layer PCL is located. The second portion P2 may be a portion where the particle layer PCL is not located. The second portion P2 may be adjacent to the first portion P1 in a direction opposite to the third direction DR3.

According to some embodiments, the magnet MG may be located under the mold MD. In this case, the plurality of particles PC may move in a direction opposite to the third direction DR3.

After the particle layer PCL is formed, the first resin part RSA and the second resin part RSB may be cured. For example, the first resin part RSA and the second resin part RSB may be thermally cured or UV cured. According to some embodiments, the first resin part RSA and the second resin part RSB may be simultaneously cured.

Referring to FIG. 16, the mold MD may be removed.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although aspects of some embodiments have been described, those skilled in the art will readily appreciate that many modifications are possible in the embodiments without materially departing from the novel teachings and characteristics of embodiments according to the present disclosure. Accordingly, all such modifications are intended to be included within the spirit and scope of embodiments according to the present disclosure as defined in the appended claims, and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A cover window comprising:
a resin part including a light transmitting area and a non-light transmitting area surrounding at least a portion of the light transmitting area; and
a particle layer inside the resin part, overlapping the non-light transmitting area, and including a plurality of particles.

2. The cover window of claim 1, wherein the resin part includes a first surface and a second surface facing the first surface, and
the particle layer is adjacent to the first surface.

3. The cover window of claim 2, wherein the particle layer is spaced apart from the second surface.

4. The cover window of claim 1, wherein each of the plurality of particles includes magnetic particle.

5. The cover window of claim 4, wherein each of the plurality of particles includes at least one of iron, nickel, cobalt, or iron oxide.

6. The cover window of claim 1, wherein a density of each of the plurality of particles and a density of the resin part are different from each other.

7. The cover window of claim 6, wherein the density of each of the plurality of particles is greater than the density of the resin part.

8. The cover window of claim 1, wherein each color of the plurality of particles is black.

9. The cover window of claim 8, wherein each of the plurality of particles includes a magnetic particle and a coating layer surrounding at least a portion of the magnetic particle, and
the coating layer has a black color.

10. The cover window of claim 1, wherein a portion of the resin part overlapping the non-light transmitting area includes:
the first portion where the particle layer is located; and
the second portion adjacent to the first portion in a thickness direction.

11. A display device comprising:
a display panel; and
a cover window on the display panel and including a light transmitting area and a non-light transmitting area surrounding at least a portion of the light transmitting area, the cover window including a resin part and a particle layer, wherein the particle layer is in the resin part, overlaps the non-light transmitting layer, and includes a plurality of particles.

12. The display device of claim 11, wherein the resin part includes a first surface and a second surface facing the first surface, and
the particle layer is adjacent to the first surface.

13. The display device of claim 12, wherein the particle layer is spaced apart from the second surface.

14. The display device of claim 11, wherein each of the plurality of particles includes a magnetic particle.

15. The display device of claim 14, wherein each of the plurality of particles includes at least one of iron, nickel, cobalt, or iron oxide.

16. A method of manufacturing a cover window comprising:
forming a first resin part overlapping a light transmitting area on a stage;
forming a second resin part overlapping a non-light transmitting area surrounding at least a portion of the light transmitting area on the stage, wherein the second resin part includes a plurality of particles;
placing a magnet to move the plurality of particles toward the magnet; and
curing the first resin part and the second resin part.

17. The method of claim 16, wherein the first resin part and the second resin part include the same material.

18. The method of claim 16, wherein each of the plurality of particles includes at least one of iron, nickel, cobalt, or iron oxide.

19. The method of claim 16, wherein the moving the plurality of particles toward the magnet includes moving the plurality of particles toward the stage by placing the magnet under the stage.

20. The method of claim 16, wherein the forming the second resin part proceeds after the forming the first resin part.
